(19) United States
(12) Patent Application Publication
(10) Pub. No.: US 2015/0179259 A1
(43) Pub. Date: Jun. 25, 2015

(54) ELECTRONIC DEVICE AND METHOD FOR FABRICATING THE SAME

(71) Applicant: SK hynix Inc., Icheon-Si (KR)

(72) Inventors: Jung-Nam Kim, Icheon-Si (KR); Jong-Han Shin, Icheon-Si (KR); Sung-Jun Kim, Icheon-Si (KR); Sang-Soo Kim, Icheon-Si (KR)

(21) Appl. No.: 14/538,715

(22) Filed: Nov. 11, 2014

(30) Foreign Application Priority Data
Dec. 23, 2013 (KR) 10-2013-0161521

(51) Int. Cl. G11C 14/00; G06F 12/08; G11C 7/10; H01L 27/105

(52) U.S. Cl. CPC G11C 14/0036; H01L 27/1052; G06F 12/0875; G11C 7/1003; G06F 2212/452; G11C 11/161

(57) ABSTRACT

An electronic device including a semiconductor memory is provided, wherein the semiconductor memory comprises: a substrate in which first to third regions are provided; first to third trenches formed in the first to third regions, respectively, and having a different line width from each other; and first to third device isolation layers formed in the first to third trenches, respectively, wherein the first device isolation layer includes a stack structure of a first insulation layer and a second insulation layer, the second device isolation layer includes the first insulation layer formed over a part of a bottom and one sidewall of the second trench, the second insulation layer having a stepped type and a third insulation layer which is formed over the second insulation layer, and the third device isolation layer includes a stack structure of the first to third insulation layers.

### CROSS-REFERENCE TO RELATED APPLICATIONS

This patent document claims priority of Korean Patent Application No. 10-2013-0161521, entitled “ELECTRONIC DEVICE AND METHOD FOR FABRICATING THE SAME,” and filed on Dec. 23, 2013, which is incorporated herein by reference in its entirety.

### TECHNICAL FIELD

This patent document relate to memory circuits or devices and their applications in electronic devices or systems.

### BACKGROUND

Recently, as electronic devices or appliances trend toward miniaturization, low power consumption, high performance, multi-functionality, and so on, there is a demand for electronic devices capable of storing information in various electronic devices or appliances such as a computer, a portable communication device, and so on, and research and development for such electronic devices have been conducted. Examples of such semiconductor devices include electronic devices which can store data using a characteristic switched between different resistance states according to an applied voltage or current, and can be implemented in various configurations, for example, an RRAM (resistive random access memory), a PRAM (phase change random access memory), an FRAM (ferroelectric random access memory), an MRAM (magnetic random access memory), an E-fuse, etc.

### SUMMARY

The disclosed technology in this patent document includes memory circuits or devices and their applications in electronic devices or systems and various implementations of an electronic device. According to the various electronic devices and a fabricating method thereof provided in this patent document, characteristics of a device can be improved, and the deterioration of a device can be prevented by removing a seam of a device isolation layer.

In one aspect, an electronic device including a semiconductor memory is provided. The semiconductor memory includes: a substrate in which first to third regions are provided; first to third trenches formed in the first to third regions, respectively, and having a different line width from each other; and first to third device isolation layers formed in the first to third trenches, respectively, wherein the first device isolation layer includes a stack structure of a first insulation layer and a second insulation layer, the second device isolation layer includes the first insulation layer formed over a part of a bottom and one sidewall of the second trench, the second insulation layer having a stepped type and a third insulation layer which is formed over the second insulation layer, and the third device isolation layer includes a stack structure of the first to third insulation layers.

In another aspect, an electronic device is provided to include a semiconductor memory which includes: a substrate having a first region, a second region and a third region adjacent to one another, wherein the second region is located between, and isolates, the first and third regions; first, second and third trenches formed in the first, second and third regions, respectively, each having a different line width ; and first, second and third device isolation layers formed in each of the first, second and third trenches, wherein the first device isolation layer includes a first stack structure including a first insulation layer and a second insulation layer, wherein the second device isolation layer in the second trench includes a first insulation layer formed over a part of a bottom and one sidewall of the second trench, and a second insulation layer formed over the first insulation layer and surfaces of the second trench not covered by the first insulation layer to have a stepped type structure, and wherein the third device isolation layer in the third trench includes a first insulation layer formed over surfaces of the third trench, a second insulation layer formed over the first insulation layer and a third insulation layer formed over the second insulation layer.

In another aspect, an electronic device is provided to include a semiconductor memory which includes: a substrate having a first region, a second region and a third region adjacent to one another, wherein the second region is located between, and isolates, the first and third regions; first, second and third trenches formed in the first, second and third regions, respectively, each having a different line width ; and first, second and third device isolation layers formed in each of the first, second and third trenches, wherein the first device isolation layer includes a first stack structure including a first insulation layer and a second insulation layer, wherein the second device isolation layer in the second trench includes a first insulation layer formed over a part of a bottom and one sidewall of the second trench, a second insulation layer formed over the first insulation layer and a third insulation layer formed over the second insulation layer and surfaces of the second trench not covered by the first insulation layer to have a stepped type structure, and wherein the third device isolation layer in the third trench includes a first insulation layer formed over surfaces of the third trench, a second insulation layer formed over the first insulation layer and a third insulation layer formed over the second insulation layer.

In some implementations, the first region may include a cell region, the second region may include a dummy trench region, and the third region may include a peripheral region. In some implementations, the first trench may have a line width smaller than line widths of the second and third trenches. In some implementations, the first and second insulation layers formed in the second and third regions include a liner type structure to define a void. In some implementations, the first and second insulation layers may include a nitride material. In some implementations, the third insulation layer may include an oxide material. In some implementations, the semiconductor memory may further include an oxide formed between the substrate and the first and or the second insulation layer.

In some implementations, the electronic device may further include a microprocessor which includes: a control unit configured to receive a signal including a command from an outside of the microprocessor, and performs extracting, decoding of the command, or controlling input or output of a signal of the microprocessor; an operation unit configured to perform an operation based on a result that the control unit decodes the command; and a memory unit configured to store data for performing the operation, data corresponding to a result of performing the operation, or an address of data for which the operation is performed, wherein the semiconductor memory is part of the memory unit in the microprocessor.

In some implementations, the electronic device may further include a processor which includes: a core unit configured to perform, based on a command inputted from an outside of the processor, an operation corresponding to the command, by using data; a cache memory unit configured to store data for performing the operation, data corresponding to a result of performing the operation, or an address of data for which the operation is performed; and a bus interface connected between the core unit and the cache memory unit, and configured to transmit data between the core unit and the cache memory unit, wherein the semiconductor memory is part of the cache memory unit in the processor.

In some implementations, the electronic device may further include a processing system which includes: a processor configured to decode a command received by the processor and control an operation for information based on a result of decoding the command; an auxiliary memory device configured to store a program for decoding the command and the information; a main memory device configured to call and store the program and the information from the auxiliary memory device such that the processor can perform the operation using the program and the information when executing the program; and an interface device configured to perform communication between at least one of the processor, the auxiliary memory device and the main memory device and the outside, wherein the semiconductor memory is part of the auxiliary memory device or the main memory device in the processing system.

In some implementations, the electronic device may further include a data storage system which includes: a storage device configured to store data and conserve stored data regardless of power supply; a controller configured to control input and output of data to and from the storage device according to a command inputted form an outside; a temporary storage device configured to temporarily store data exchanged between the storage device and the outside; and an interface configured to perform communication between at least one of the storage device, the controller and the temporary storage device and the outside, wherein the semiconductor memory is part of the storage device or the temporary storage device in the data storage system.

In some implementations, the electronic device may further include a memory system which includes: a memory configured to store data and conserve stored data regardless of power supply; a memory controller configured to control input and output of data to and from the memory according to a command inputted form an outside; a buffer memory configured to buffer data exchanged between the memory and the outside; and an interface configured to perform communication between at least one of the memory, the memory controller and the buffer memory and the outside, wherein the semiconductor memory is part of the memory or the buffer memory in the memory system.

In another aspect, a method for fabricating an electronic device including a semiconductor memory is provided. The method may include: forming first to third trenches in a substrate in which first to third regions are provided, respectively, the first to third trenches having a different line width from each other; forming a first insulation layer over the first to third trenches to have a thickness for filling the first trench; forming a protection layer over the first insulation layer to expose the first insulation layer of the first region; etching the first insulation layer of the first region to a certain depth, and the protection layer; forming a second insulation layer over the first insulation layer to have a thickness for filling the first trench; forming a third insulation layer over the second insulation layer to have a thickness for filling the third trench; and forming device isolation layers by etching the first to third insulation layers.

In another aspect, a method for fabricating an electronic device including a semiconductor memory is provided. The method may include: forming first, second and third trenches in first, second and third regions in a substrate, respectively, each of the first, second and third trenches having a different line width, the second region being located between the first and first regions; forming a first insulation layer over the first, second and third trenches to have a thickness that fills up the first trench; forming a protection layer over the first insulation layer to cover the first, the second and the third regions; etching the protection layer and the first insulation layer in the first region to remove the protection layer and to remove part of the first insulation layer of the first region to be recessed to a certain depth; forming a second insulation layer over the first insulation layer to have a thickness for filling the first trench; forming a third insulation layer over the second insulation layer to have a thickness for filling the second and third trenches; and forming device isolation layers in the first, second and third regions by etching the first, second and third insulation layers.

In some implementations, the first region may include a cell region, the second region may include a dummy trench region, and the third region may include a peripheral region. In some implementations, the first trench may be formed to have a line width smaller than line widths of the second and third trenches. In some implementations, the first and second insulation layers may include a nitride material. In some implementations, the protection layer and the third insulation layer may include an oxide material. In some implementations, the protection layer may include high temperature oxide (HTO) or tetra ethyle ortho silicate (TEOS). In some implementations, the third insulation layer may include silicon oxide (SiO2). In some implementations, the forming of the protection layer includes: forming a mask pattern over the first insulation layer of the second and third regions to expose the first insulation layer of the first region; and removing the mask pattern and the protection layer of the first region. In some implementations, during the etching of the first insulation layer and the protection layer of the first region, the first insulation layer of the third region may remain or be etched to a given thickness. In some implementations, the certain depth of the first insulation layer is sufficient to remove a seam which occurs in the first insulation. In some implementations, the etching the first insulation layer and the protection layer of the first region is performed by a wet etch. In some implementations, the etching of the first insulation layer and the protection layer of the first region is performed using phosphoric acid (H2PO4) solution. In some implementations, the method may further comprising forming a sidewall oxide over sidewalls and bottoms of the first to third trenches before forming the first insulation layer. In some implementations, in the etching the first insulation layer of the first region to a certain depth and the protection layer, the sidewall oxide may be etched by a predetermined thickness.

In another aspect, an electronic device is provided to include a semiconductor memory which comprises: a substrate including a first trench in a first region, a second trench in a second region and a third trench in a third region, the second region being located between the first and third regions to separate the first region from the third region; a first device isolation layer formed in the first trench in the first region and including a first insulation layer formed over surfaces of the first trench and a second insulation layer formed over the first insulation layer to fill up the first trench; a second device isolation layer formed in the second trench in the second region and including a stack structure including the first and second insulation layers to form a liner type structure to cover surfaces of the second trench, wherein each of the first and second insulation layers has a stepped portion at a bottom surface of the second trench; and a third device isolation layer formed in the third trench in the third region and including a stack structure including the first and second insulation layers.

In some implementations, the first device isolation layer has a smaller width than those of the second and third device isolation layers. In some implementations, the second and third device isolation layers further include a third isolation layer formed over the stack structure in the second and third trenches. In some implementations, the second insulation layer of the first trench is free from a seam.

These and other aspects, implementations and associated advantages are described in greater detail in the drawings, the description and the claims.

### BRIEF DESCRIPTION OF THE DRAWINGS

FIG. 1 is a cross-sectional view of an example of a semiconductor device in accordance with an implementation of the disclosed technology.

FIGS. 2A through 2K are cross-sectional views for explaining an example of a method for fabricating a semiconductor device in accordance with an implementation of the disclosed technology.

FIG. 3 is an example of configuration diagram of a microprocessor including memory circuitry based on the disclosed technology.

FIG. 4 is an example of configuration diagram of a processor including memory circuitry based on the disclosed technology.

FIG. 5 is an example of configuration diagram of a system including memory circuitry based on the disclosed technology.

FIG. 6 is an example of configuration diagram of a data storage system including memory circuitry based on the disclosed technology.

FIG. 7 is an example of configuration diagram of a memory system including memory circuitry based on the disclosed technology.

### DETAILED DESCRIPTION

Various examples and implementations of the disclosed technology are described below in detail with reference to the accompanying drawings.

The drawings may not be necessarily to scale and in some instances, proportions of at least some of structures in the drawings may have been exaggerated in order to clearly illustrate certain features of the described examples or implementations. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure may not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

As the degree of integration of various semiconductor devices has been increased and a design rule becomes simplified, the dimension of a pattern of the semiconductor device is becoming finer. Accordingly, in semiconductor memory devices with memory cells, a region for forming a memory cell is substantially reduced. As a semiconductor device has been developed to provide high degree of integration with micro size, the overall chip area is also increased in proportion to an increase in the memory capacity. To achieve a desired high memory capacity, more patterns need to be formed in a limited cell region and each pattern needs to have micro size with a reduced linewdith.

The semiconductor device is provided with a device isolation layer for isolating adjacent unit components. The device isolation layer is formed through a shallow trench isolation (STI) process. The STI process is a method for fabricating the device isolation layer by forming a trench in a substrate and filling an insulation material inside the trench. The STI process may be applied in a Giga-density semiconductor device fabricating technology in some current and future implementations.

As the design rule becomes simplified, nitride is used as a gap-filling material for a device isolation layer since the device isolation layer is buried by a liner nitride layer when a cell region has a narrower linewidth. However, when the nitride is used as the device isolation layer, a seam occurs in the device isolation layer, which deteriorates the performance of a device.

Accordingly, the disclosed technology in this patent document includes memory circuits or devices and their applications in electronic devices or systems and various implementations of an electronic device in which the improvement of characteristics of a device is possible, and the deterioration of a device can be prevented by removing a seam of a device isolation layer, and a fabricating method thereof.

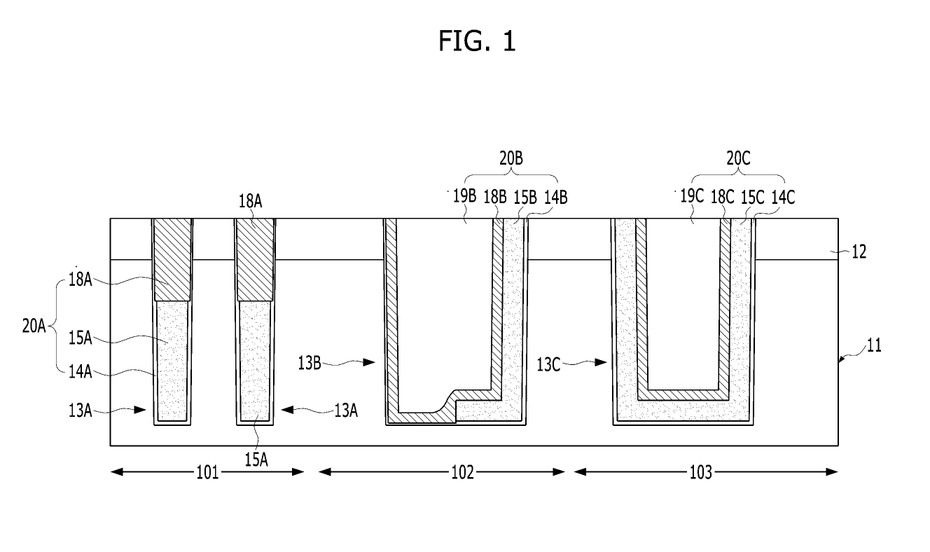

FIG. 1 is a cross-sectional view of a semiconductor device in accordance with an implementation of the disclosed technology in this patent document.

Referring to FIG. 1, first to third trenches 13A, 13B and 13C are formed in a structure in which a hard mask pattern 12 is formed over a semiconductor substrate 11 including a first region 101, a second region 102 and a third region 103. Each of the first to third trenches 13A to 13C may be formed to have a different line width from one another. The first trench 13A may have a line width smaller than that of the second and third trenches 13B and 13C. For example, the first region 101 may include a cell region, and the third region 103 may include a peripheral region. Further, the second region 102 may include a dummy trench region for isolating the first region 101 from the third region 103. To isolate the cell region in the first region 101 and the peripheral region in the third region 103, the second region 102 may be disposed between the first region 101 and the third region 103.

A device isolation layer 20A formed in the first trench 13A within the first region 101 may include a stack structure of sidewall oxide 14A, a first insulation layer 15A and a second insulation layer 18A. The sidewall oxide 14A is formed as a confirming layer or coating over sidewalls and a bottom of the first trench 13A as a liner or lining type structure inside the first trench 13A, the first insulation layer 15A is formed over the sidewall oxide 14A on the bottom and sidewalls of the first trench 13A to fill a lower part of the first trench 13A, and the second insulation layer 18A is formed over the first insulation layer 15A, and is surrounded by the layer of the sidewall oxide 14A on the sidewalls of the first trench 13A, to fill an upper part of the first trench 13A.

A device isolation layer 20C formed in the third trench 13C within the third region 103 may include a stack structure of sidewall oxide 14C, a first insulation layer 15C, a second insulation layer 18C, and a third insulation layer 19C in an arrangement different from the structure in the device isolation layer 20A in the first trench 13A. Similarly to the sidewall oxide 14A in the first trench 13A, the sidewall oxide 14C is formed as a conforming layer or coating over sidewalls and a bottom of the third trench 13C as a first liner or lining type structure inside the third trend 13C. However, the first insulation layer 15C is formed as a conforming layer or coating over the sidewall oxide 14C as a second liner or lining type structure over the first liner or lining structure 14C, and the second insulation layer 18C is formed as a conforming layer or coating over the first insulation layer 15C as a third liner or lining type structure over the second liner or lining structure 15C. The remaining part of the third trench 13C is filled up by the third insulation layer 19C over the second insulation layer 18C.

A dummy device isolation layer 20B is formed in the second region 102 between the first and third regions 101 and 103 to include a first insulation layer 15B, a second insulation layer 18B, and a third insulation layer 19B. Similar to the first and third trenches 13A and 13C, a confirming layer or coating of oxide 14B is formed over sidewalls and a bottom of the second trench 13B as a first liner or lining type structure inside the second trend 13B. The first insulation layer 15B is structured as a second liner or lining type structure over the first liner or lining type structure 14B, but, different from the second liner or lining type structure 15C in the third trench 13C, is formed over only a part of a bottom and one sidewall of the second trench 13B as a partial liner or lining in the second trench 13B. The second insulation layer 18B is formed as a conforming layer or coating along inner surfaces of the second trench 13B including the first insulation layer 15B and the exposed bottom surface and sidewalls of the oxide 14B not covered by the first insulation layer 15B. Due to the presence of the partial liner or lining type structure by the first insulation layer 15B, the second insulation layer 18B may have a stepped liner or lining type structure. The third insulation layer 19B is formed over sidewalls and bottom of the second insulation layer 18B to fill the second trench 13B.

In various implementations, the first insulation layers 15A, 15B and 15C and the second insulation layers 18A, 18B and 18C may include a nitride material, and the third insulations layers 19B and 19C may include an oxide material. The device isolation layer 20A formed in the first region 101 may include a stack structure of nitride materials in some implementations. The device isolation layer 20C formed in the third region 103 may include a stack structure of the oxide material and the nitride material having a liner or lining type structure. The dummy device isolation layer 20B formed in the second region 102 may include a stack structure of the oxide material and the nitride material, which have a stepped liner or lining type structure.

As described above, the disclosed technology in this patent document provides the device isolation layer including the first and the second insulation layer 15A and 18As, which are separately formed in a region with a narrower line width such as the first region 101. Accordingly, it is possible to avoid the formation of a seam and thus, prevent the deterioration of a device. Furthermore, since the second region 102 is additionally disposed between the first region 101 and the third region 103 to isolate the first region 101 from the third region 103, a process margin can be secured during a device isolation process including a patterning process. As a result, since the difficulty level of the process is reduced, the process can carried out more easily.

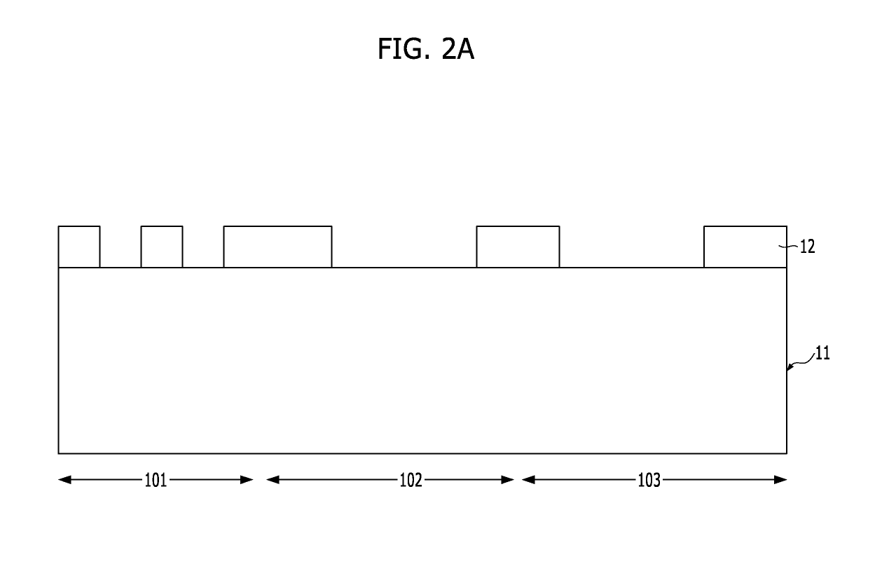

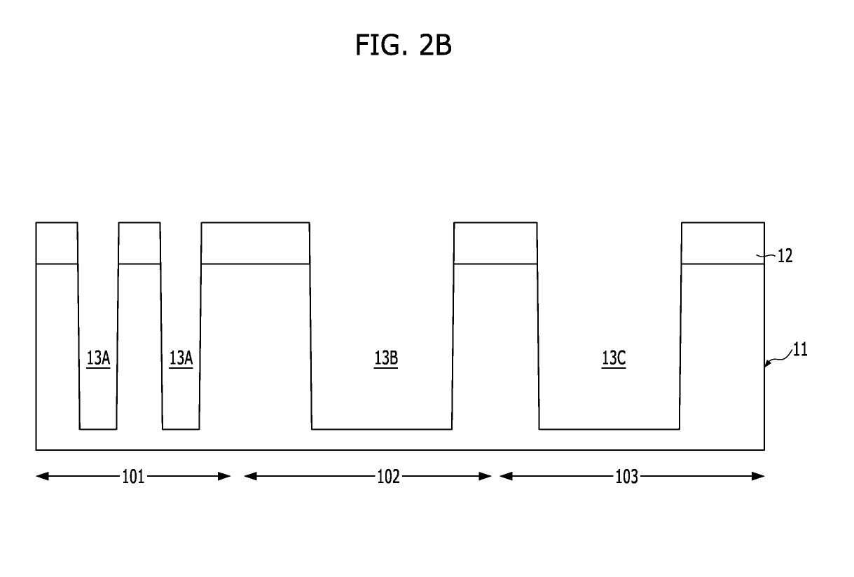

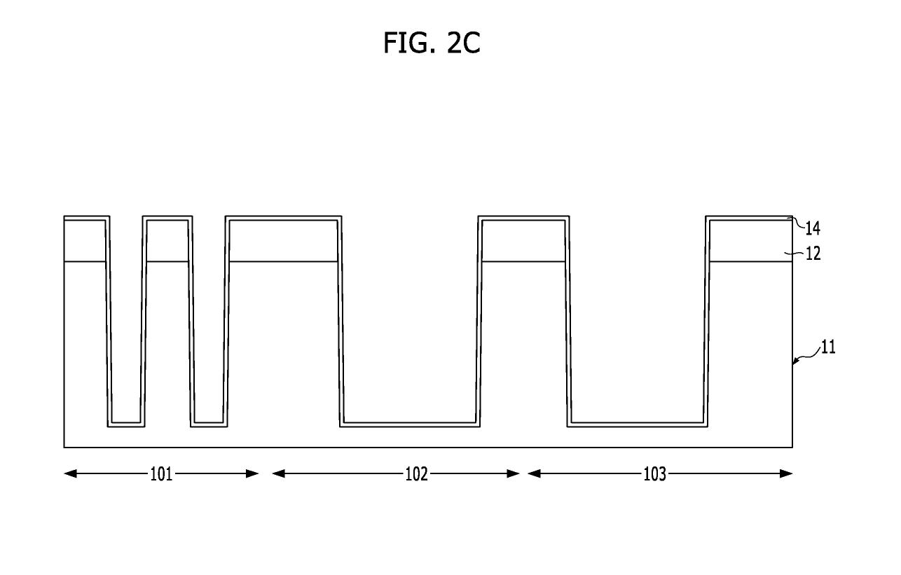

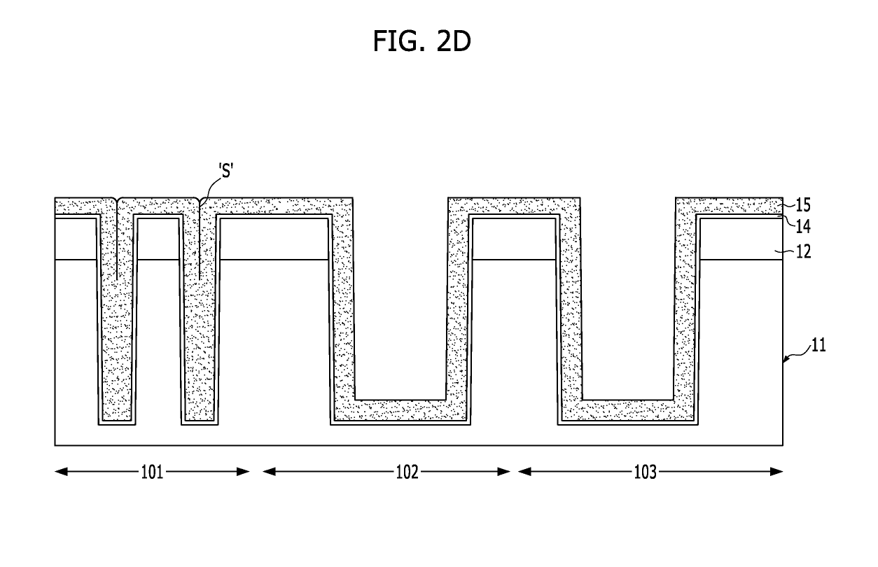

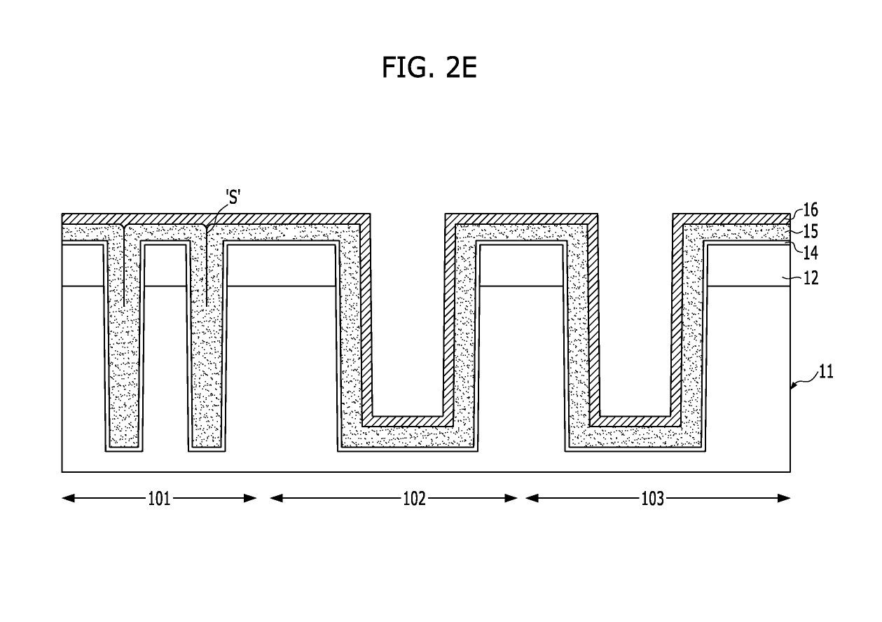

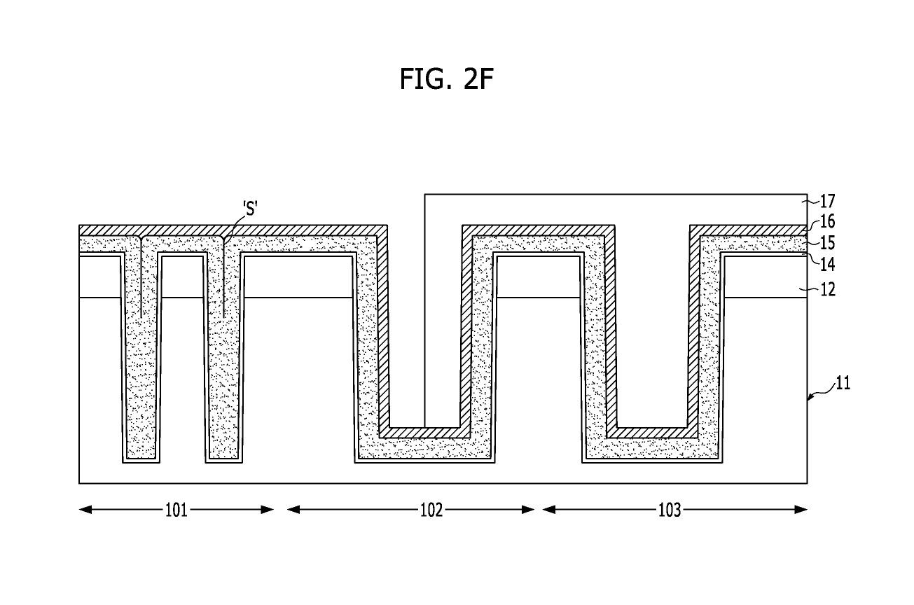

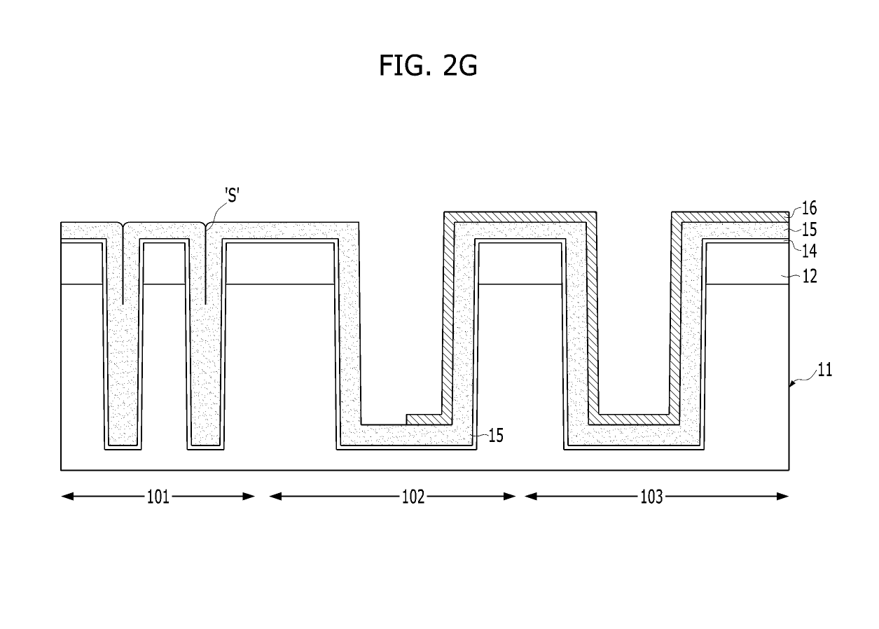

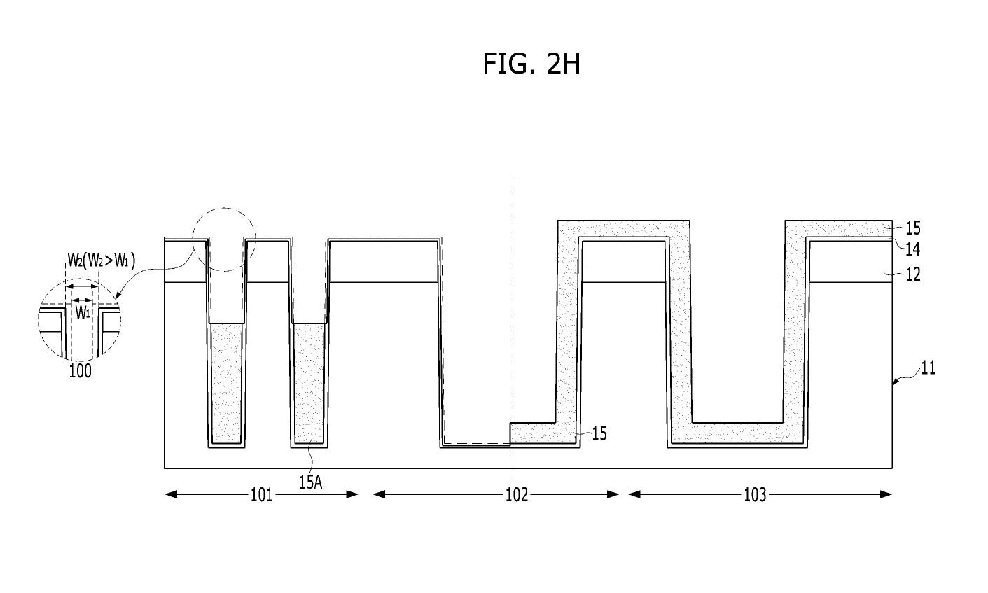

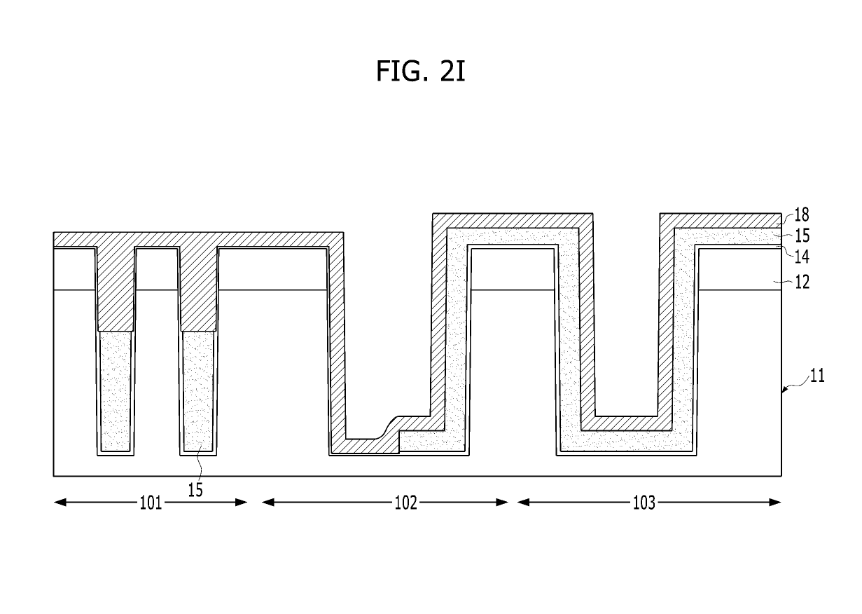

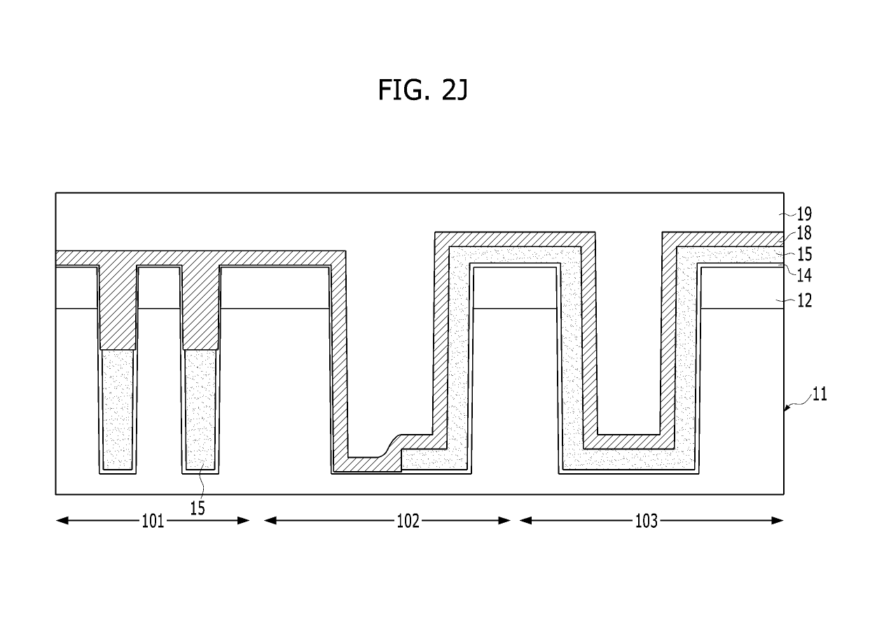

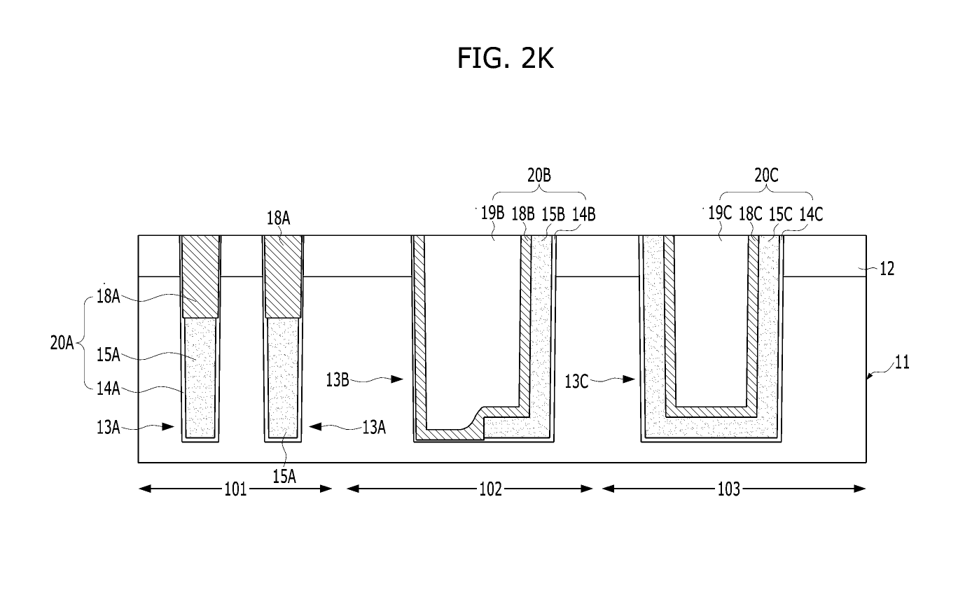

FIGS. 2A to 2J are cross-sectional views for explaining an example of a method for fabricating a semiconductor device in accordance with an implementation. In FIGS. 2A to 2J, the elements which are identical with the constituent elements shown in FIG. 1 are indicated with the same reference numerals, and like reference numerals are used to refer to the same elements.

Referring to FIG. 2A, a hard mask pattern 12 is formed over a semiconductor substrate 11 including a first region 101, a second region 102 and a third region 103. The semiconductor substrate 11 may include a silicon substrate or a silicon germanium substrate in some implementations and may include other suitable semiconductor materials in other implementations. The first region 101 may include a cell region for, e.g., forming memory cells, and the third region 103 may include a peripheral region for, e.g., forming circuitry in connection with operation of the memory cells in the cell region within the first region 101. Further, the second region 102 may include a dummy trench region without having any functional circuitry disposed between the first region 101 and the third region 103 to provide desired isolation therebetween. If the first region 101 is the cell region, the second region 102 may be disposed at the outer side of the cell region to serve as a dummy trench region for isolating the first region 101 from the third region 103 of the peripheral region.

The disclosed technology in this patent document is not limited to this implementation and other implementations are also possible for defining regions. The first region 101 may include a region in which a trench having a relatively narrower line width is formed, and the third region 103 may include a region in which a trench having a relatively broader line width is formed.

The hard mask pattern 12 is provided to perform various functions. For example, the hard mask pattern 12 can serve as an etch barrier during a process for forming a subsequent trench. Further, the hard mask pattern 12 can serve as a target layer for a planarization during a subsequent process for forming another device isolation layer. For example, the hard mask pattern 12 can also serve as an etch stop layer during a planarization process. The hard mask pattern 12 may include a material having an etch selectivity to the semiconductor substrate 11. To form a trench, the hard mask pattern 12 may be formed to have a thickness sufficient to etch the semiconductor substrate 11.

Referring to FIG. 2B, a first trench 13A, a second trench 13B and a third trench 13C are formed by etching the semiconductor substrate 11. The semiconductor substrate 11 may be etched using the hard mask pattern 12 as an etch barrier. The trenches 13A, 13B and 13C may each have a different line width and are formed in the first to third regions 101 to 103, respectively. The first trench 13A having a relatively narrower line width may be formed in the first region 101, and the second and third trenches 13B and 13C having a relatively broader line width than the first trench 13A may be formed in the second and third regions 102 and 103, respectively.

Referring to FIG. 2C, a sidewall oxide 14 is formed as a conforming layer or coating over sidewalls and bottoms of the first to third trenches 13A to 13C. The oxide 14 is formed over all exposed surfaces the first to third trenches 13A to 13C including sidewalls and bottom surfaces within the trenches. The oxide layer 14 inside the trenches, including sidewall oxide 14, may serve to prevent a stress between the semiconductor substrate 11 and gap-fill materials to be formed in the first to third trenches 13A to 13C, i.e., first to third insulation layers as described with respect to FIG. 1. The oxide layer 14 including sidewall oxide 14 may be formed by oxidizing an exposed surface of the first to third trenches 13A to 13C, or by depositing an oxide material over a resultant structure including the first to third trenches 13A to 13C. As shown in FIG. 1, the oxide layers 14 inside the sidewalls and bottom surfaces of the trenches 13A, 13B and 13C are marked by 14A in the first trench 13A, 14B in the second trench 13B and 14C in the third trench 13C.

Referring to FIG. 2D, a first insulation layer 15 is formed over the oxide layer 14 including each sidewall oxide 14. The first insulation layer 15 may include, in some implementations, an insulation material whose volume is not reduced during an annealing process. The insulation material may include a nitride material or another suitable insulation material. For example, the nitride material may include a nitride layer or a nitride-containing compound material.

Due to the difference in linewidths of the first to third trenches 13A to 13C, the same formation process for depositing the first insulation material layer 15 may fill up the narrowest trench such as the trench 13A at a faster rate than filling up wider trenches such as the second and third trenches 13B and 13C. When the first insulation layer 15 completely fills up the first trench 13A, the wider second and third trenches 13B and 13C are not yet filled up with the first insulation material 15 such that the filled first insulation material 15 in each of the second and third trenches 13B and 13C has a liner or lining type structure with a void inside the second and third trenches 13B and 13C. After the narrowest trench 13A is filled up by the first insulation material 15, the process of forming the first insulation material 15 is terminated and the resultant structure is shown in FIG. 2D. At this time, a seam ‘S’ may occur in the first insulation layer 15 filled in the first trench 13A due to a deposition characteristic of the nitride layer. Such a seam needs to be removed since the deterioration of a device may be incurred during a subsequent process. For example, the presence of such a seam may adversely affect the structural shape or integrity of a structure subsequently formed over the first insulation layer 15 located above or near the seam and thus may deteriorate the intended operation, desired performance or reliability of the device. In the disclosed technology in this patent document, a process of removing the first insulation layer 15 in which the seam ‘S’ is formed, and re-deposition a gap-fill insulation layer may be performed to achieve a seam-free insulation layer 15 before subsequent layers or structures are formed. This process will be explained below in detail with references to FIGS. 2E through 2K.

Referring to FIG. 2E, next to the formation of the first insulation layer 15 according to the process of the disclosed technology, a protection layer 16 is formed over the first insulation layer 15 having the naturally occurring but undesired seam in the narrowest trench 13A. The protection layer 16 may serve to prevent an attack on, or undesired removal of, the third region 103 when the first insulation layer 15 of the first region 101 is removed. The protection layer 16 may include a material which can be easily removed by a wet etch or another suitable removal process. The protection layer 16 may include an oxide material. For example, the oxide material may include high temperature oxide (HTO) or tetra ethyle ortho silicate (TEOS).

Referring to FIG. 2F, a mask pattern 17 is formed over the protection layer 16 of the third region 103 in the following manners. A photoresist layer (not shown) is coated on the protection layer 16 of the first to third regions 101 to 103. Then, exposure and development processes are performed on the photoresist layer to open the first region 101 by selectively removing a portion of the mask pattern 17 over the first region 101 while retaining a portion of the mask pattern 17 over part of the second region 102 and the entirety of the third region 103. If the first region 101 is the cell region, the mask pattern 17 may be a cell open mask pattern.

As a result of the above selective removal of the mask pattern 17, the protection layer 16 in the first region 101 is exposed by the mask pattern 17. As illustrated, a part of the protection layer 16 in the second region 102 (including a part in the second trench 13B) is also exposed.

At this time, the mask pattern 17 to open the first region 101 may be patterned to open a part of the second region 102 and cover the remainder of the second region 102. Since the second region 102 includes the dummy trench region which serves to isolate the first region 101 from the third region 103 while not affecting a practical operation of the device, the mask pattern 17 may be patterned on the basis of the second region 102. Thus, a process margin for patterning the mask pattern 17 can be further secured by a line width of the second region 102, and a patterning process can be more easily carried out.

Next, a wet etch or another suitable removal process is performed to remove the exposed portions of the protection layer 16 and the mask pattern 17 in the first region 101 and the third region 103, respectively. Referring to FIG. 2G, the protection layer (‘16’ shown in FIG. 2F) of the first region 101 and the mask pattern (‘17’ shown in FIG. 2F) of the third region 103 are removed. The protection layer 16 and the mask pattern 17 may be simultaneously removed. The wet etch or another suitable removal process may be performed until the first insulation layer 15 of the first region 101 is exposed and the mask pattern 17 of the third region 103 is completely removed while exposing the portion of the protection layer 16 previously covered by the mask pattern 17 in part of the second region 102 and in the entire third region 103.

Upon completing the above removal in FIG. 2G, the first insulation layer 15 is exposed in the first region 101 and a protection layer 16A remains on the first insulation layer 15 in the third region 103. In the second region 102, depending on whether the mask pattern 17 exists or not at different locations, the first insulation layer 15 is exposed in a part of the second region 102 while the protection layer 16A remains on the first insulation layer 15 in the remainder of the second region 102.

Referring to FIG. 2H, the first insulation layer (‘15’ shown in FIG. 2G) of the first region 101 is recessed to a certain depth. The first insulation layer 15 may be etched by a wet etch or another suitable removal process. For instance, if the first insulation layer 15 includes a nitride material, the wet etch may be performed using a phosphoric acid (H₂PO₄) solution. The first insulation layer 15 exposed in the second region 102 is etched by the same wet etch as the first insulation layer 15 of the first region 101. Accordingly, the first insulation layer 15 exposed in the second region 102 may be recessed to a certain depth and may remain on the second region 102 with a thickness identical to the first insulation layer 15 of the first region 101.

The wet etch may be performed to completely remove the seam ‘S’ in the first trench (‘13A’ shown in FIG. 2B). In particular, the seam ‘S’ is fully etched so as not to remain on the first insulation layer 15 of the first region 101. At this time, the exposed oxide 14 including sidewall oxide 14 may be etched as well by a predetermined thickness.

Accordingly, as shown in the numeral reference ‘100’ of FIG. 2H, a line width of an upper portion of the first trench 13A increases from a first width ‘W₁’ to a second width ‘W₂.’ As a result, a gap-filling margin may be secured during a subsequent process for etching a second insulation layer.

While the wet etch is performed for the first insulation layer 15 in the first region 101 and a part of the second region 102, the first insulation layer 15 of the third region 103 may be not be removed due to the protection layer (‘16A’ shown in FIG. 2G). Rather, the first insulation layer 15 of the third region 103 remains or may be etched partially to a given thickness while still covering the underlying structure. The protection layer 16A may be removed when the wet etch is finished. In other words, the first insulation layer 15 has an etch selectivity different from the protection layer 16A, and the first insulation layer 15 has an etch ratio greater than that of the protection layer 16A.

In the second region 102, the same process may be performed on the first insulation layer 15 protected by the protection layer 16A in the second region 102 as the first insulation layer 15 protected by the protection layer 16A in the third region 103. For example, the first insulation layer 15 protected by the protection layer 16A in the second region 102 may not be etched away or removed due to the protection layer 16A. Rather, the first insulation layer 15 in the second region 102 remains or may be etched to the given thickness while still covering the underlying structure. The protection layer 16A may be removed when the wet etch is finished.

In the implementation of the disclosed technology in this patent document, the first insulation layer 15 of the first region 101 recessed by the wet etch is referred to as a reference numeral ‘15A’, and the first insulation layer 15 remaining on the third region 103 is referred to as the reference numeral ‘15C’. In the second region 102, both of the first insulation layer 15A recessed by the wet etch and the first insulation layer 15C protected by the protection layer 16A are provided. Accordingly, a stepped first insulation layer 15A and 15B may be formed in the second trench (‘13B’ shown in FIG. 2B). For convenience of explanation, the first insulation layer 15C remaining on the second region 102 is referred to as a reference numeral ‘15B’.

Referring to FIG. 2I, a second insulation layer 18 is formed over the resultant structure including the first insulation layers 15A to 15C. The second insulation layer 18 may be formed to have a thickness for filling the upper portion of the first trench (‘13A’ shown in FIG. 2B) in the first region 101. The second insulation layer 18 may be formed to have a liner or lining type structure in the second region 102 and the third region 103, similar to the first insulation layers 15B and 15C. The second insulation layer 18 may be formed with the same material as the insulation material used in the first insulation layers 15A to 15C. The second insulation layer 18 may include a nitride material or other suitable materials. For instance, the nitride material may include a nitride layer.

Since the second insulation layer 18 is deposited over the first insulation layer 15A, a gap-filling height of the first region 101 becomes lower. Further, a line width of the upper portion of the first trench 13A increases due to the etched sidewall oxide 14. Due those conditions, the second insulation layer 18 may be formed in the first trench 13A without an occurrence of the seam in the first insulation layer 15 in the first trench 13A as shown in FIG. 2D. In the second region 102, the second insulation layer 18 may be formed to have a liner or lining type structure over the oxide layer 14B and the first insulation layer 15B with a stepped portion due to the stepped portion of the first insulation layer 15B.

Referring to FIG. 2J, next in the process, a third insulation layer 19 is formed over the second insulation layer 18. The third insulation layer 19 may be formed to have a thickness for filling the second and third trenches (‘13B’ and ‘13C’ shown in FIG. 2B). The third insulation layer 19 may include a gap-filling material. The third insulation layer 19 may include an oxide material or other suitable materials. For instance, the oxide material may include silicon oxide (SiO₂).

Referring to FIG. 2K, a device isolation layer 20A, a dummy device isolation layer 20B and a device isolation layer 20C are formed in the first to third regions 101 to 103, respectively. To form the device isolation layers 20A to 20C, the third insulation layer (‘19’ shown in FIG. 2J) and the second insulation layer (‘18’ shown in FIG. 2J) may be etched until the hard mask pattern 12 is exposed. The third insulation layer 19 and the second insulation layer 18 may be etched by a planarization process. For example, the planarization process may include a chemical mechanical polishing (CMP) process. In the second region 102, the dummy device isolation layer 20B is formed to have the first insulation layers 15B and 18B having stepped portions, The dummy device isolation layer 20B does not affect the practical operation of the device.

As is apparent from the above descriptions, in the semiconductor device and the method for fabricating the same in accordance with the implementations, the deterioration of a device can be prevented by removing a seam in a device isolation layer so that the final device structure is free the undesired seam.

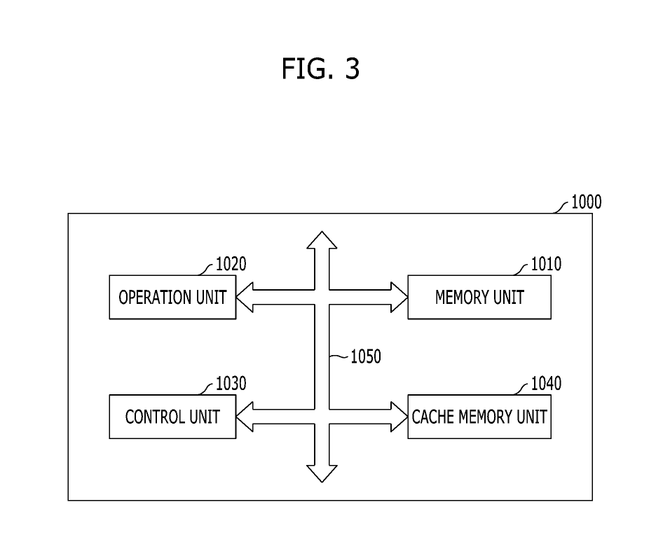

The above and other memory circuits or semiconductor devices based on the disclosed technology can be used in a range of devices or systems. FIGS. 3-7 provide some examples of devices or systems that can implement the memory circuits disclosed herein.

FIG. 3 is an example of configuration diagram of a microprocessor implementing memory circuitry based on the disclosed technology.

Referring to FIG. 3, a microprocessor 1000 may perform tasks for controlling and tuning a series of processes of receiving data from various external devices, processing the data, and outputting processing results to external devices. The microprocessor 1000 may include a memory unit 1010, an operation unit 1020, a control unit 1030, and so on. The microprocessor 1000 may be various data processing units such as a central processing unit (CPU), a graphic processing unit (GPU), a digital signal processor (DSP) and an application processor (AP).

The memory unit 1010 is a part which stores data in the microprocessor 1000, as a processor register, register or the like. The memory unit 1010 may include a data register, an address register, a floating point register and so on. Besides, the memory unit 1010 may include various registers. The memory unit 1010 may perform the function of temporarily storing data for which operations are to be performed by the operation unit 1020, result data of performing the operations and addresses where data for performing of the operations are stored. The memory unit 1010 may include one or more of the above-described semiconductor devices in accordance with the implementations. For example, the memory unit 1010 may include a substrate in which first to third regions are provided; first to third trenches formed in the first to third regions, respectively, and having a different line width from each other; and first to third device isolation layers formed in the first to third trenches, respectively, wherein the first device isolation layer includes a stack structure of a first insulation layer and a second insulation layer, the second device isolation layer includes the first insulation layer formed over a part of a bottom and one sidewall of the second trench, the second insulation layer having a stepped type and a third insulation layer which is formed over the second insulation layer, and the third device isolation layer includes a stack structure of the first to third insulation layers. Through this, a process margin of the memory unit 1010 may be secured, and a deterioration of device is prevented, thereby improving the data storage characteristics of the memory unit 1010. As a consequence, a fabrication process of the microprocessor 1000 may become easy and performance characteristics of the microprocessor 1000 may be improved.

The operation unit 1020 may perform four arithmetical operations or logical operations according to results that the control unit 1030 decodes commands. The operation unit 1020 may include at least one arithmetic logic unit (ALU) and so on.

The control unit 1030 may receive signals from the memory unit 1010, the operation unit 1020 and an external device of the microprocessor 1000, perform extraction, decoding of commands, and controlling input and output of signals of the microprocessor 1000, and execute processing represented by programs.

The microprocessor 1000 according to the present implementation may additionally include a cache memory unit 1040 which can temporarily store data to be inputted from an external device other than the memory unit 1010 or to be outputted to an external device. In this case, the cache memory unit 1040 may exchange data with the memory unit 1010, the operation unit 1020 and the control unit 1030 through a bus interface 1050.

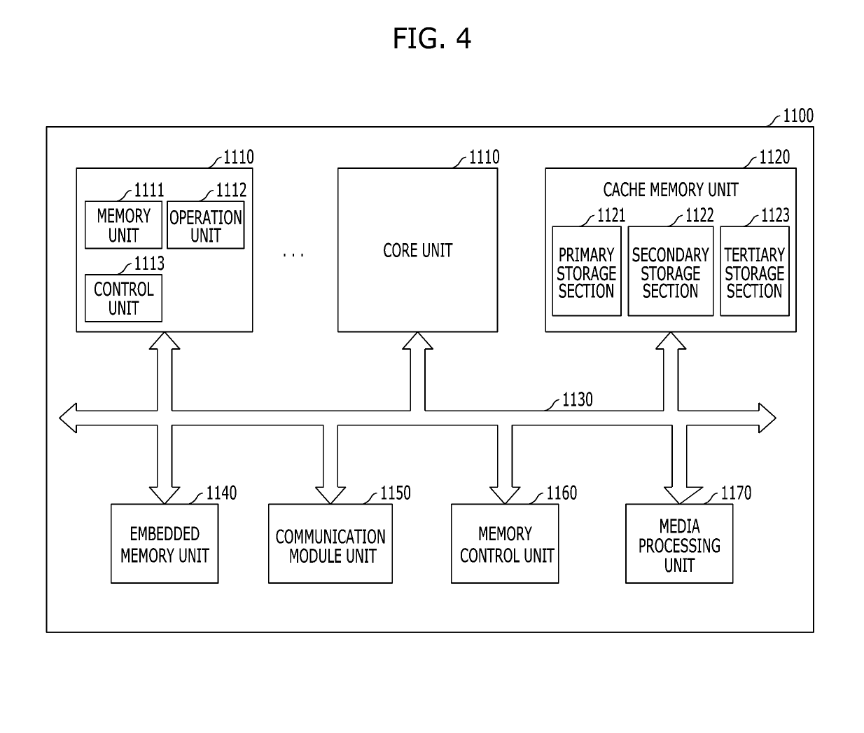

FIG. 4 is an example of configuration diagram of a processor implementing memory circuitry based on the disclosed technology.

Referring to FIG. 4, a processor 1100 may improve performance and realize multi-functionality by including various functions other than those of a microprocessor which performs tasks for controlling and tuning a series of processes of receiving data from various external devices, processing the data, and outputting processing results to external devices. The processor 1100 may include a core unit 1110 which serves as the microprocessor, a cache memory unit 1120 which serves to storing data temporarily, and a bus interface 1130 for transferring data between internal and external devices. The processor 1100 may include various system-on-chips (SoCs) such as a multi-core processor, a graphic processing unit (GPU) and an application processor (AP).

The core unit 1110 of the present implementation is a part which performs arithmetic logic operations for data inputted from an external device, and may include a memory unit 1111, an operation unit 1112 and a control unit 1113.

The memory unit 1111 is a part which stores data in the processor 1100, as a processor register, a register or the like. The memory unit 1111 may include a data register, an address register, a floating point register and so on. Besides, the memory unit 1111 may include various registers. The memory unit 1111 may perform the function of temporarily storing data for which operations are to be performed by the operation unit 1112, result data of performing the operations and addresses where data for performing of the operations are stored. The operation unit 1112 is a part which performs operations in the processor 1100. The operation unit 1112 may perform four arithmetical operations, logical operations, according to results that the control unit 1113 decodes commands, or the like. The operation unit 1112 may include at least one arithmetic logic unit (ALU) and so on. The control unit 1113 may receive signals from the memory unit 1111, the operation unit 1112 and an external device of the processor 1100, perform extraction, decoding of commands, controlling input and output of signals of processor 1100, and execute processing represented by programs.

The cache memory unit 1120 is a part which temporarily stores data to compensate for a difference in data processing speed between the core unit 1110 operating at a high speed and an external device operating at a low speed. The cache memory unit 1120 may include a primary storage section 1121, a secondary storage section 1122 and a tertiary storage section 1123. In general, the cache memory unit 1120 includes the primary and secondary storage sections 1121 and 1122, and may include the tertiary storage section 1123 in the case where high storage capacity is required. As the occasion demands, the cache memory unit 1120 may include an increased number of storage sections. That is to say, the number of storage sections which are included in the cache memory unit 1120 may be changed according to a design. The speeds at which the primary, secondary and tertiary storage sections 1121, 1122 and 1123 store and discriminate data may be the same or different. In the case where the speeds of the respective storage sections 1121, 1122 and 1123 are different, the speed of the primary storage section 1121 may be largest. At least one storage section of the primary storage section 1121, the secondary storage section 1122 and the tertiary storage section 1123 of the cache memory unit 1120 may include one or more of the above-described semiconductor devices in accordance with the implementations. For example, the cache memory unit 1120 may include a substrate in which first to third regions are provided; first to third trenches formed in the first to third regions, respectively, and having a different line width from each other; and first to third device isolation layers formed in the first to third trenches, respectively, wherein the first device isolation layer includes a stack structure of a first insulation layer and a second insulation layer, the second device isolation layer includes the first insulation layer formed over a part of a bottom and one sidewall of the second trench, the second insulation layer having a stepped type and a third insulation layer which is formed over the second insulation layer, and the third device isolation layer includes a stack structure of the first to third insulation layers. Through this, a process margin of the cache memory unit 1120 may be secured, and a deterioration of device is prevented, thereby improving the data storage characteristics of the cache memory unit 1120. As a consequence, a fabrication process of the microprocessor 1000 may become easy and performance characteristics of the processor 1100 may be improved.

Although it was shown in FIG. 4 that all the primary, secondary and tertiary storage sections 1121, 1122 and 1123 are configured inside the cache memory unit 1120, it is to be noted that all the primary, secondary and tertiary storage sections 1121, 1122 and 1123 of the cache memory unit 1120 may be configured outside the core unit 1110 and may compensate for a difference in data processing speed between the core unit 1110 and the external device. Meanwhile, it is to be noted that the primary storage section 1121 of the cache memory unit 1120 may be disposed inside the core unit 1110 and the secondary storage section 1122 and the tertiary storage section 1123 may be configured outside the core unit 1110 to strengthen the function of compensating for a difference in data processing speed. In another implementation, the primary and secondary storage sections 1121, 1122 may be disposed inside the core units 1110 and tertiary storage sections 1123 may be disposed outside core units 1110.

The bus interface 1130 is a part which connects the core unit 1110, the cache memory unit 1120 and external device and allows data to be efficiently transmitted.

The processor 1100 according to the present implementation may include a plurality of core units 1110, and the plurality of core units 1110 may share the cache memory unit 1120. The plurality of core units 1110 and the cache memory unit 1120 may be directly connected or be connected through the bus interface 1130. The plurality of core units 1110 may be configured in the same way as the above-described configuration of the core unit 1110. In the case where the processor 1100 includes the plurality of core unit 1110, the primary storage section 1121 of the cache memory unit 1120 may be configured in each core unit 1110 in correspondence to the number of the plurality of core units 1110, and the secondary storage section 1122 and the tertiary storage section 1123 may be configured outside the plurality of core units 1110 in such a way as to be shared through the bus interface 1130. The processing speed of the primary storage section 1121 may be larger than the processing speeds of the secondary and tertiary storage section 1122 and 1123. In another implementation, the primary storage section 1121 and the secondary storage section 1122 may be configured in each core unit 1110 in correspondence to the number of the plurality of core units 1110, and the tertiary storage section 1123 may be configured outside the plurality of core units 1110 in such a way as to be shared through the bus interface 1130.

The processor 1100 according to the present implementation may further include an embedded memory unit 1140 which stores data, a communication module unit 1150 which can transmit and receive data to and from an external device in a wired or wireless manner, a memory control unit 1160 which drives an external memory device, and a media processing unit 1170 which processes the data processed in the processor 1100 or the data inputted from an external input device and outputs the processed data to an external interface device and so on. Besides, the processor 1100 may include a plurality of various modules and devices. In this case, the plurality of modules which are added may exchange data with the core units 1110 and the cache memory unit 1120 and with one another, through the bus interface 1130.

The embedded memory unit 1140 may include not only a volatile memory but also a nonvolatile memory. The volatile memory may include a DRAM (dynamic random access memory), a mobile DRAM, an SRAM (static random access memory), and a memory with similar functions to above mentioned memories, and so on. The nonvolatile memory may include a ROM (read only memory), a NOR flash memory, a NAND flash memory, a phase change random access memory (PRAM), a resistive random access memory (RRAM), a spin transfer torque random access memory (STTRAM), a magnetic random access memory (MRAM), a memory with similar functions.

The communication module unit 1150 may include a module capable of being connected with a wired network, a module capable of being connected with a wireless network and both of them. The wired network module may include a local area network (LAN), a universal serial bus (USB), an Ethernet, power line communication (PLC) such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB) such as various devices which send and receive data without transmit lines, and so on.

The memory control unit 1160 is to administrate and process data transmitted between the processor 1100 and an external storage device operating according to a different communication standard. The memory control unit 1160 may include various memory controllers, for example, devices which may control IDE (Integrated Device Electronics), SATA (Serial Advanced Technology Attachment), SCSI (Small Computer System Interface), RAID (Redundant Array of Independent Disks), an SSD (solid state disk), eSATA (External SATA), PCMCIA (Personal Computer Memory Card International Association), a USB (universal serial bus), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The media processing unit 1170 may process the data processed in the processor 1100 or the data inputted in the forms of image, voice and others from the external input device and output the data to the external interface device. The media processing unit 1170 may include a graphic processing unit (GPU), a digital signal processor (DSP), a high definition audio device (HD audio), a high definition multimedia interface (HDMI) controller, and so on.

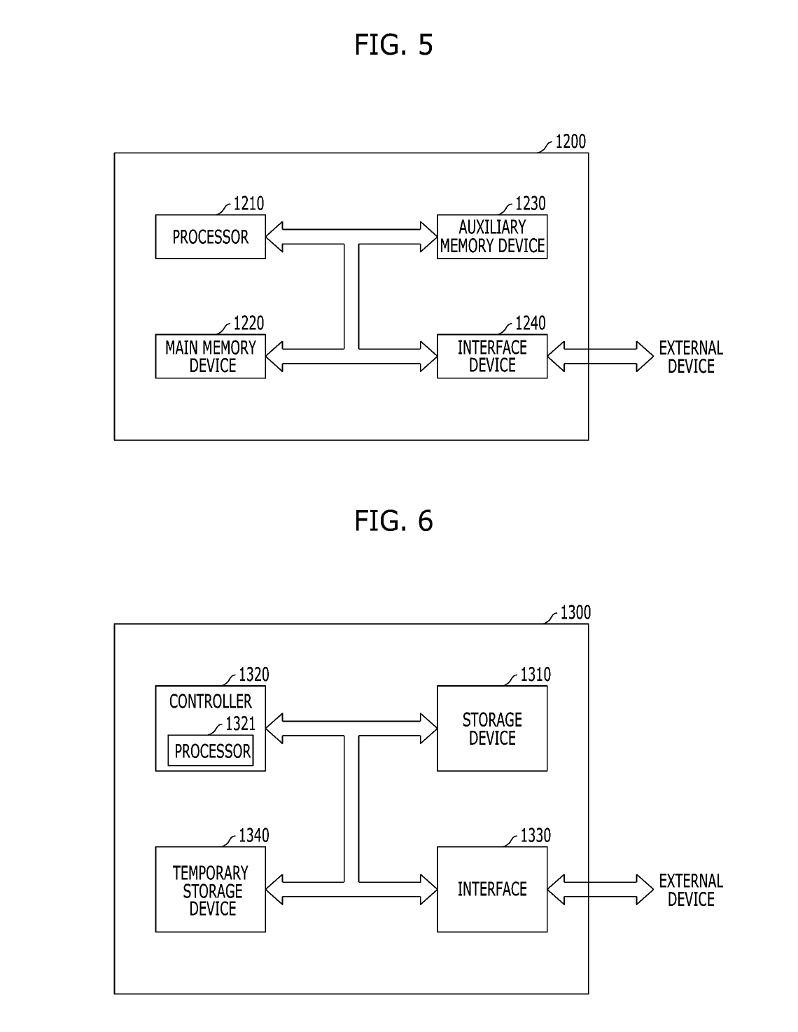

FIG. 5 is an example of configuration diagram of a system implementing memory circuitry based on the disclosed technology.

Referring to FIG. 5, a system 1200 as an apparatus for processing data may perform input, processing, output, communication, storage, etc. to conduct a series of manipulations for data. The system 1200 may include a processor 1210, a main memory device 1220, an auxiliary memory device 1230, an interface device 1240, and so on. The system 1200 of the present implementation may be various electronic systems which operate using processors, such as a computer, a server, a PDA (personal digital assistant), a portable computer, a web tablet, a wireless phone, a mobile phone, a smart phone, a digital music player, a PMP (portable multimedia player), a camera, a global positioning system (GPS), a video camera, a voice recorder, a telematics, an audio visual (AV) system, a smart television, and so on.

The processor 1210 may decode inputted commands and processes operation, comparison, etc. for the data stored in the system 1200, and controls these operations. The processor 1210 may include a microprocessor unit (MPU), a central processing unit (CPU), a single/multi-core processor, a graphic processing unit (GPU), an application processor (AP), a digital signal processor (DSP), and so on.

The main memory device 1220 is a storage which can temporarily store, call and execute program codes or data from the auxiliary memory device 1230 when programs are executed and can conserve memorized contents even when power supply is cut off. The main memory device 1220 may include one or more of the above-described semiconductor devices in accordance with the implementations. For example, the main memory device 1220 may include a substrate in which first to third regions are provided; first to third trenches formed in the first to third regions, respectively, and having a different line width from each other; and first to third device isolation layers formed in the first to third trenches, respectively, wherein the first device isolation layer includes a stack structure of a first insulation layer and a second insulation layer, the second device isolation layer includes the first insulation layer formed over a part of a bottom and one sidewall of the second trench, the second insulation layer having a stepped type and a third insulation layer which is formed over the second insulation layer, and the third device isolation layer includes a stack structure of the first to third insulation layers. Through this, a process margin of the main memory device 1220 may be secured, and a deterioration of device is prevented, thereby improving the data storage characteristics of the main memory device 1220. As a consequence, a fabrication process of the processor 1210 may become easy and performance characteristics of the microprocessor 1000 may be improved. Also, the main memory device 1220 may further include a static random access memory (SRAM), a dynamic random access memory (DRAM), and so on, of a volatile memory type in which all contents are erased when power supply is cut off. Unlike this, the main memory device 1220 may not include the semiconductor devices according to the implementations, but may include a static random access memory (SRAM), a dynamic random access memory (DRAM), and so on, of a volatile memory type in which all contents are erased when power supply is cut off.

The auxiliary memory device 1230 is a memory device for storing program codes or data. While the speed of the auxiliary memory device 1230 is slower than the main memory device 1220, the auxiliary memory device 1230 can store a larger amount of data. The auxiliary memory device 1230 may include one or more of the above-described semiconductor devices in accordance with the implementations. For example, the auxiliary memory device 1230 may include a substrate in which first to third regions are provided; first to third trenches formed in the first to third regions, respectively, and having a different line width from each other; and first to third device isolation layers formed in the first to third trenches, respectively, wherein the first device isolation layer includes a stack structure of a first insulation layer and a second insulation layer, the second device isolation layer includes the first insulation layer formed over a part of a bottom and one sidewall of the second trench, the second insulation layer having a stepped type and a third insulation layer which is formed over the second insulation layer, and the third device isolation layer includes a stack structure of the first to third insulation layers. Through this, a process margin of the auxiliary memory device 1230 may be secured, and a deterioration of device is prevented, thereby improving the data storage characteristics of the auxiliary memory device 1230. As a consequence, a fabrication process of the microprocessor 1000 may become easy and performance characteristics of the microprocessor 1000 may be improved. Also, the auxiliary memory device 1230 may further include a data storage system (see the reference numeral 1300 of FIG. 5) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. Unlike this, the auxiliary memory device 1230 may not include the semiconductor devices according to the implementations, but may include data storage systems (see the reference numeral 1300 of FIG. 5) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The interface device 1240 may be to perform exchange of commands and data between the system 1200 of the present implementation and an external device. The interface device 1240 may be a keypad, a keyboard, a mouse, a speaker, a mike, a display, various human interface devices (HIDs), a communication device, and so on. The communication device may include a module capable of being connected with a wired network, a module capable of being connected with a wireless network and both of them. The wired network module may include a local area network (LAN), a universal serial bus (USB), an Ethernet, power line communication (PLC), such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), such as various devices which send and receive data without transmit lines, and so on.

FIG. 6 is an example of configuration diagram of a data storage system implementing memory circuitry based on the disclosed technology.

Referring to FIG. 6, a data storage system 1300 may include a storage device 1310 which has a nonvolatile characteristic as a component for storing data, a controller 1320 which controls the storage device 1310, an interface 1330 for connection with an external device, and a temporary storage device 1340 for storing data temporarily. The data storage system 1300 may be a disk type such as a hard disk drive (HDD), a compact disc read only memory (CDROM), a digital versatile disc (DVD), a solid state disk (SSD), and so on, and a card type such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The storage device 1310 may include a nonvolatile memory which stores data semi-permanently. The nonvolatile memory may include a ROM (read only memory), a NOR flash memory, a NAND flash memory, a phase change random access memory (PRAM), a resistive random access memory (RRAM), a magnetic random access memory (MRAM), and so on.

The controller 1320 may control exchange of data between the storage device 1310 and the interface 1330. To this end, the controller 1320 may include a processor 1321 for performing an operation for, processing commands inputted through the interface 1330 from an outside of the data storage system 1300 and so on.

The interface 1330 is to perform exchange of commands and data between the data storage system 1300 and the external device. In the case where the data storage system 1300 is a card type, the interface 1330 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. In the case where the data storage system 1300 is a disk type, the interface 1330 may be compatible with interfaces, such as IDE (Integrated Device Electronics), SATA (Serial Advanced Technology Attachment), SCSI (Small Computer System Interface), eSATA (External SATA), PCMCIA (Personal Computer Memory Card International Association), a USB (universal serial bus), and so on, or be compatible with the interfaces which are similar to the above mentioned interfaces. The interface 1330 may be compatible with one or more interfaces having a different type from each other.

The temporary storage device 1340 can store data temporarily for efficiently transferring data between the interface 1330 and the storage device 1310 according to diversifications and high performance of an interface with an external device, a controller and a system. The temporary storage device 1340 for temporarily storing data may include one or more of the above-described semiconductor devices in accordance with the implementations. The temporary storage device 1340 may include a substrate in which first to third regions are provided; first to third trenches formed in the first to third regions, respectively, and having a different line width from each other; and first to third device isolation layers formed in the first to third trenches, respectively, wherein the first device isolation layer includes a stack structure of a first insulation layer and a second insulation layer, the second device isolation layer includes the first insulation layer formed over a part of a bottom and one sidewall of the second trench, the second insulation layer having a stepped type and a third insulation layer which is formed over the second insulation layer, and the third device isolation layer includes a stack structure of the first to third insulation layers. Through this, a process margin of the temporary storage device 1340 may be secured, and a deterioration of device is prevented, thereby improving the data storage characteristics of the temporary storage device 1340. As a consequence, a fabrication process of the data storage system 1300 may become easy and performance characteristics of the microprocessor 1000 may be improved.

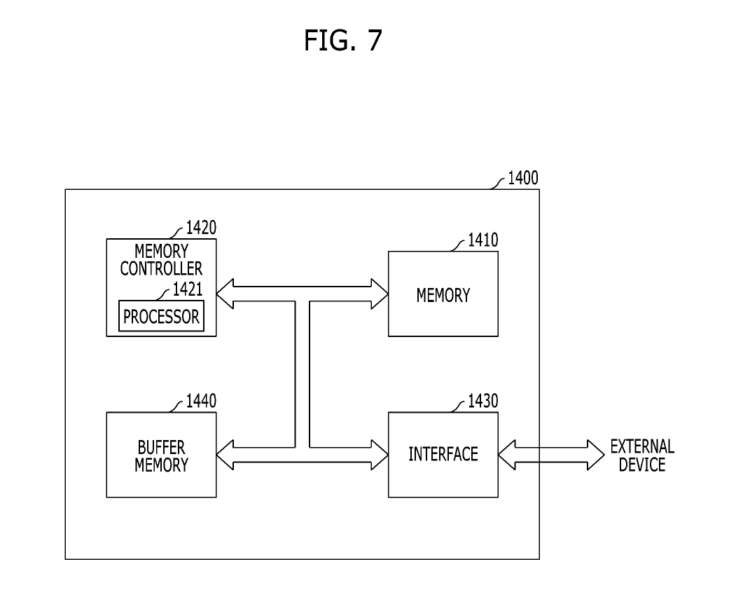

FIG. 7 is an example of configuration diagram of a memory system implementing memory circuitry based on the disclosed technology.

Referring to FIG. 7, a memory system 1400 may include a memory 1410 which has a nonvolatile characteristic as a component for storing data, a memory controller 1420 which controls the memory 1410, an interface 1430 for connection with an external device, and so on. The memory system 1400 may be a card type such as a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The memory 1410 for storing data may include one or more of the above-described semiconductor devices in accordance with the implementations. For example, the memory 1410 may include a substrate in which first to third regions are provided; first to third trenches formed in the first to third regions, respectively, and having a different line width from each other; and first to third device isolation layers formed in the first to third trenches, respectively, wherein the first device isolation layer includes a stack structure of a first insulation layer and a second insulation layer, the second device isolation layer includes the first insulation layer formed over a part of a bottom and one sidewall of the second trench, the second insulation layer having a stepped type and a third insulation layer which is formed over the second insulation layer, and the third device isolation layer includes a stack structure of the first to third insulation layers. Through this, a process margin of the memory 1410 may be secured, and a deterioration of device is prevented, thereby improving the data storage characteristics of the memory 1410. As a consequence, a fabrication process of the memory system 1400 may become easy and performance characteristics of the microprocessor 1000 may be improved.

Also, the memory 1410 according to the present implementation may further include a ROM (read only memory), a NOR flash memory, a NAND flash memory, a phase change random access memory (PRAM), a resistive random access memory (RRAM), a magnetic random access memory (MRAM), and so on, which have a nonvolatile characteristic.

The memory controller 1420 may control exchange of data between the memory 1410 and the interface 1430. To this end, the memory controller 1420 may include a processor 1421 for performing an operation for and processing commands inputted through the interface 1430 from an outside of the memory system 1400.

The interface 1430 is to perform exchange of commands and data between the memory system 1400 and the external device. The interface 1430 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. The interface 1430 may be compatible with one or more interfaces having a different type from each other.

The memory system 1400 according to the present implementation may further include a buffer memory 1440 for efficiently transferring data between the interface 1430 and the memory 1410 according to diversification and high performance of an interface with an external device, a memory controller and a memory system. For example, the buffer memory 1440 for temporarily storing data may include one or more of the above-described semiconductor devices in accordance with the implementations. The buffer memory 1440 may include a substrate in which first to third regions are provided; first to third trenches formed in the first to third regions, respectively, and having a different line width from each other; and first to third device isolation layers formed in the first to third trenches, respectively, wherein the first device isolation layer includes a stack structure of a first insulation layer and a second insulation layer, the second device isolation layer includes the first insulation layer formed over a part of a bottom and one sidewall of the second trench, the second insulation layer having a stepped type and a third insulation layer which is formed over the second insulation layer, and the third device isolation layer includes a stack structure of the first to third insulation layers. Through this, a process margin of the buffer memory 1440 may be secured, and a deterioration of device is prevented, thereby improving the data storage characteristics of the memory unit 1010 i. As a consequence, a fabrication process of the memory system 1400 may become easy and performance characteristics of the microprocessor 1000 may be improved.

Moreover, the buffer memory 1440 according to the present implementation may further include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic. Unlike this, the buffer memory 1440 may not include the semiconductor devices according to the implementations, but may include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic.

As is apparent from the above descriptions, in the semiconductor device and the method for fabricating the same in accordance with the implementations, patterning of a resistance variable element is easy, and it is possible to secure the characteristics of the resistance variable element.

Features in the above examples of electronic devices or systems in FIGS. 3-7 based on the memory devices disclosed in this document may be implemented in various devices, systems or applications. Some examples include mobile phones or other portable communication devices, tablet computers, notebook or laptop computers, game machines, smart TV sets, TV set top boxes, multimedia servers, digital cameras with or without wireless communication functions, wrist watches or other wearable devices with wireless communication capabilities.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described. Other implementations, enhancements and variations can be made based on what is described and illustrated in this patent document.

What is claimed is:

1. An electronic device including a semiconductor memory, wherein the semiconductor memory comprises:
a substrate having a first region, a second region and a third region adjacent to one another, wherein the second region is located between, and isolates, the first and third regions;
first, second and third trenches formed in the first, second and third regions, respectively, each having a different line width; and
first, second and third device isolation layers formed in each of the first, second and third trenches,
wherein the first device isolation layer includes a first stack structure including a first insulation layer and a second insulation layer,
wherein the second device isolation layer in the second trench includes a first insulation layer formed over a part of a bottom and one sidewall of the second trench, a second insulation layer formed over the first insulation layer and a third insulation layer formed over the second insulation layer and surfaces of the second trench not covered by the first insulation layer to have a stepped type structure, and
wherein the third device isolation layer in the third trench includes a first insulation layer formed over surfaces of the third trench, a second insulation layer formed over the first insulation layer and a third insulation layer formed over the second insulation layer.

2. The electronic device of claim 1, wherein the first region includes a cell region, the second region includes a dummy trench region, and the third region includes a peripheral region.

3. The electronic device of claim 1, wherein the first trench has a line width smaller than line widths of the second and third trenches.

4. The electronic device of claim 1, wherein the first and second insulation layers formed in the second and third regions include a liner type structure to define a void.

5. The electronic device of claim 1, wherein the first and second insulation layers include a nitride material.

6. The electronic device of claim 1, wherein the third insulation layer includes an oxide material.

7. The electronic device of claim 1, further including:
an oxide formed between the substrate and the first or the second insulation layer.

8. The electronic device according to claim 1, further comprising a microprocessor which includes:
a control unit configured to receive a signal including a command from an outside of the microprocessor, and performs extracting, decoding of the command, or controlling input or output of a signal of the microprocessor;
an operation unit configured to perform an operation based on a result that the control unit decodes the command; and
a memory unit configured to store data for performing the operation, data corresponding to a result of performing the operation, or an address of data for which the operation is performed,
wherein the semiconductor memory is part of the memory unit in the microprocessor.

9. The electronic device according to claim 1, further comprising a processor which includes:
a core unit configured to perform, based on a command inputted from an outside of the processor, an operation corresponding to the command, by using data;
a cache memory unit configured to store data for performing the operation, data corresponding to a result of performing the operation, or an address of data for which the operation is performed; and
a bus interface connected between the core unit and the cache memory unit, and configured to transmit data between the core unit and the cache memory unit,
wherein the semiconductor memory is part of the cache memory unit in the processor.

10. The electronic device according to claim 1, further comprising a processing system which includes:
a processor configured to decode a command received by the processor and control an operation for information based on a result of decoding the command;
an auxiliary memory device configured to store a program for decoding the command and the information;
a main memory device configured to call and store the program and the information from the auxiliary memory device such that the processor can perform the operation using the program and the information when executing the program; and
an interface device configured to perform communication between at least one of the processor, the auxiliary memory device and the main memory device and the outside,
wherein the semiconductor memory is part of the auxiliary memory device or the main memory device in the processing system.

11. The electronic device according to claim 1, further comprising a data storage system which includes:
a storage device configured to store data and conserve stored data regardless of power supply;
a controller configured to control input and output of data to and from the storage device according to a command inputted form an outside;
a temporary storage device configured to temporarily store data exchanged between the storage device and the outside; and
an interface configured to perform communication between at least one of the storage device, the controller and the temporary storage device and the outside,
wherein the semiconductor memory is part of the storage device or the temporary storage device in the data storage system.

12. The electronic device according to claim 1, further comprising a memory system which includes:
a memory configured to store data and conserve stored data regardless of power supply;
a memory controller configured to control input and output of data to and from the memory according to a command inputted form an outside;
a buffer memory configured to buffer data exchanged between the memory and the outside; and
an interface configured to perform communication between at least one of the memory, the memory controller and the buffer memory and the outside,
wherein the semiconductor memory is part of the memory or the buffer memory in the memory system.

13. An electronic device including a semiconductor memory, wherein the semiconductor memory comprises:
a substrate including a first trench in a first region, a second trench in a second region and a third trench in a third region, the second region being located between the first and third regions to separate the first region from the third region;
a first device isolation layer formed in the first trench in the first region and including a first insulation layer formed over surfaces of the first trench and a second insulation layer formed over the first insulation layer to fill up the first trench;
a second device isolation layer formed in the second trench in the second region and including a stack structure including the first and second insulation layers to form a liner type structure to cover surfaces of the second trench, wherein each of the first and second insulation layers has a stepped portion at a bottom surface of the second trench; and
a third device isolation layer formed in the third trench in the third region and including a stack structure including the first and second insulation layers.

14. The electronic device of claim 13, wherein the first device isolation layer has a smaller width than those of the second and third device isolation layers.

15. The electronic device of claim 13, wherein the second and third device isolation layers further include a third isolation layer formed over the stack structure in the second and third trenches.

16. The electronic device of claim 13, wherein the second insulation layer of the first trench is free of a seam.

17. The electronic device according to claim 13, further comprising a microprocessor which includes:
a control unit configured to receive a signal including a command from an outside of the microprocessor, and performs extracting, decoding of the command, or controlling input or output of a signal of the microprocessor;
an operation unit configured to perform an operation based on a result that the control unit decodes the command; and
a memory unit configured to store data for performing the operation, data corresponding to a result of performing the operation, or an address of data for which the operation is performed,
wherein the semiconductor memory is part of the memory unit in the microprocessor.

18. The electronic device according to claim 13, further comprising a processor which includes:
a core unit configured to perform, based on a command inputted from an outside of the processor, an operation corresponding to the command, by using data;
a cache memory unit configured to store data for performing the operation, data corresponding to a result of performing the operation, or an address of data for which the operation is performed; and
a bus interface connected between the core unit and the cache memory unit, and configured to transmit data between the core unit and the cache memory unit,
wherein the semiconductor memory is part of the cache memory unit in the processor.

19. The electronic device according to claim 13, further comprising a processing system which includes:
a processor configured to decode a command received by the processor and control an operation for information based on a result of decoding the command;
an auxiliary memory device configured to store a program for decoding the command and the information;
a main memory device configured to call and store the program and the information from the auxiliary memory device such that the processor can perform the operation using the program and the information when executing the program; and
an interface device configured to perform communication between at least one of the processor, the auxiliary memory device and the main memory device and the outside,
wherein the semiconductor memory is part of the auxiliary memory device or the main memory device in the processing system.

20. The electronic device according to claim 13, further comprising a data storage system which includes:
a storage device configured to store data and conserve stored data regardless of power supply;
a controller configured to control input and output of data to and from the storage device according to a command inputted form an outside;
a temporary storage device configured to temporarily store data exchanged between the storage device and the outside; and
an interface configured to perform communication between at least one of the storage device, the controller and the temporary storage device and the outside,
wherein the semiconductor memory is part of the storage device or the temporary storage device in the data storage system.

21. The electronic device according to claim 1, further comprising a memory system which includes:
a memory configured to store data and conserve stored data regardless of power supply;
a memory controller configured to control input and output of data to and from the memory according to a command inputted form an outside;
a buffer memory configured to buffer data exchanged between the memory and the outside; and
an interface configured to perform communication between at least one of the memory, the memory controller and the buffer memory and the outside,
wherein the semiconductor memory is part of the memory or the buffer memory in the memory system.
